(19) United States
(12) Patent Application Publication
(10) Pub. No.: US 2013/0050969 A1
(43) Pub. Date: Feb. 28, 2013

(54) STORAGE CARD

(71) Applicants: WEI-DONG CONG, Shenzhen City (CN); GUO-YI CHEN, Shenzhen City (CN)

(72) Inventors: WEI-DONG CONG, Shenzhen City (CN); GUO-YI CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/228,457

(22) Filed: Sep. 9, 2011

(30) Foreign Application Priority Data
Aug. 25, 2011 (CN) 201110246233.6

(51) Int. Cl. H05K 1/14; H05K 1/18

(52) U.S. Cl. 361/785

(57) ABSTRACT

A storage card includes a circuit board, a USB interface arranged on the circuit board and connected to a storage device interface of a motherboard. A control chip arranged on the circuit board and connected to the USB interface, and a number of storage chips arranged on the circuit board and connected to the control chip and the USB interface. A first extending board is extended from a bottom edge of the circuit board, to be inserted into an expansion slot of the motherboard.

### BACKGROUND

1. Technical Field

The present disclosure relates to a storage card.

2. Description of Related Art

Users, such as music lovers and photographers, store audio and graphics data on their computer systems. Thus, users must upgrade their current hard disk drives for bigger hard disk drives or must add hard disk drives, or add other memory storage devices. However, the hard disk drives are expensive, and the memories cannot be hot plugged from the expansion slot when the motherboard is powered up. Game enthusiasts prefer high-quality pictures and better sound quality, they connect separate graphics cards and sound cards to expansion slots, such as to peripheral component interconnection (PCI) slots arranged on the motherboards of the computer systems. However, hard disk drives are difficult to install and game enthusiasts cannot make full use of all of their computer expansion slots. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawing, like reference numerals designate corresponding parts throughout the several views.

FIG. 1 is a schematic view of a storage card in accordance with an exemplary embodiment of the present disclosure.

FIG. 2 is an assembled view of the storage card of FIG. 1 connected to a motherboard.

### DETAILED DESCRIPTION

The disclosure, including the drawings, is illustrated by way of examples and not by way of limitation. References to “an” or “one” embodiment in this disclosure are not necessarily to the same embodiment, and such references mean at least one.

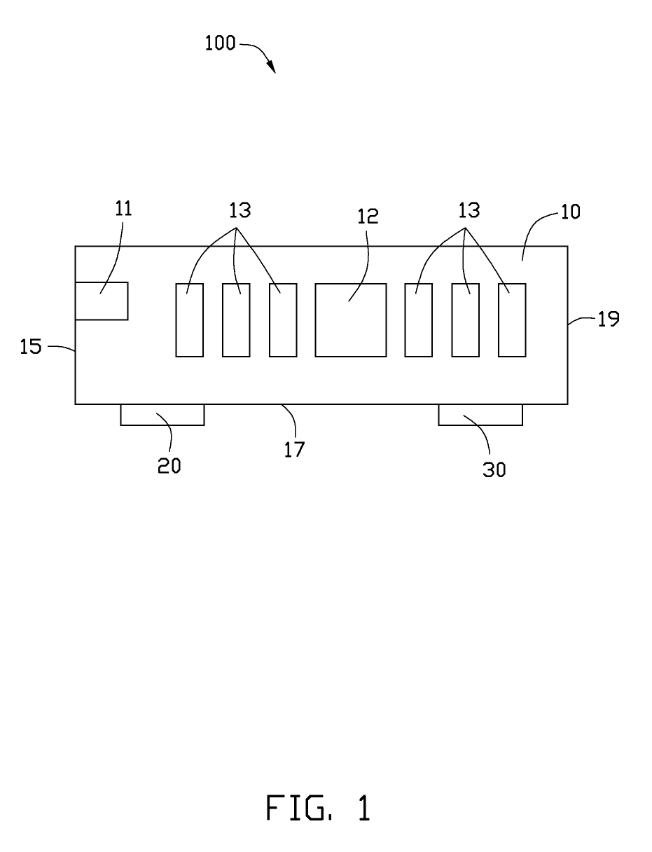

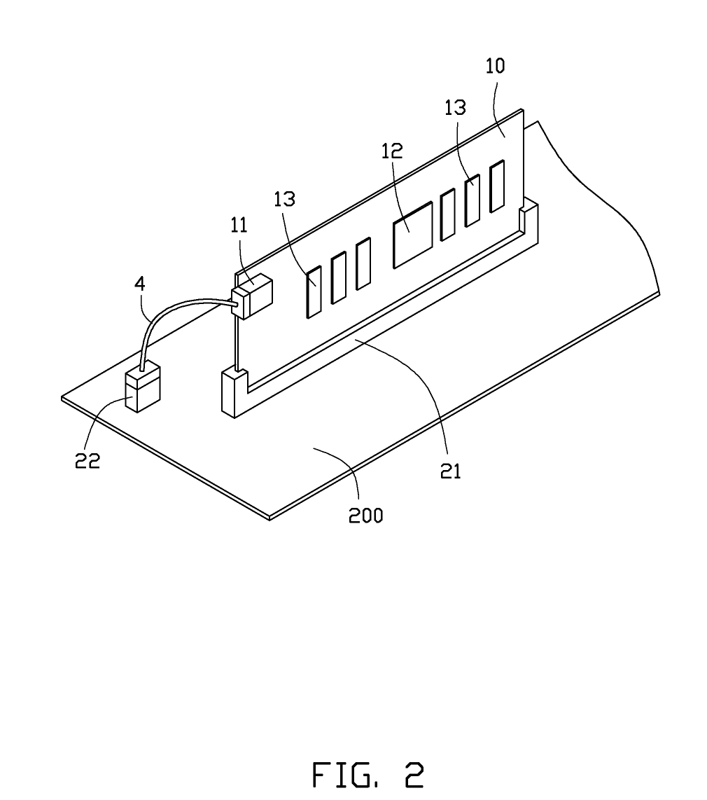

Referring to FIGS. 1 and 2, a storage card 100 in accordance with an exemplary embodiment includes a substantially rectangular circuit board 10. A USB interface 11, a control chip 12, and a plurality of storage chips 13 are arranged on the circuit board 10. A motherboard 200 includes an expansion slot 21 and a storage device interface 22. The USB interface 11 is located adjacent to a short edge 15 of the circuit board 10, and connected to the control chip 12 and the storage chips 13. The USB interface 11 is connected to the storage device interface 22 of the motherboard 200 through a cable 4, to provide a voltage received from the motherboard 200 to the control chip 12 and the storage chips 13, and provide a control signal received from the motherboard 200 to the control chip 12. The control chip 12 is connected to the storage chips 13, to control the storage chips 13 to store data. A first extending board 20 and a second extending board 30 are respectively extended from a long edge 17 of the circuit board 10 and located adjacent to two opposite short edges 15 and 19 of the circuit board 10, to be inserted into the expansion slot 21 of the motherboard 200 for fixing the storage card 100 on the motherboard 200.

In one embodiment, the storage device interface 22 is a USB interface. The expansion slot 21 is a peripheral component interconnection (PCI) expansion slot. In other embodiments, the expansion slot 21 may be one of a double data rate type three (DDR3) memory slot, a double data rate type two (DDR2) memory slot, and a peripheral component interconnection express (PCIe) expansion slot.

In assembly, the storage card 100 can be mounted in the expansion slot 21 through the first and second extending boards 20 and 30, to fix the storage card 100 on the motherboard 200. The USB interface 11 is connected to the storage device interface 22 through the cable 4 with two USB storage device interfaces.

In use, when the motherboard 200 receives power, the motherboard 200 outputs a voltage to the control chip 12 and the storage chips 13 through the storage device interface 22, the cable 4, and the USB interface 11. At the same time, the motherboard 200 also outputs a control signal to the control chip 12 through the storage device interface 22, the cable 4, and the USB interface 11, to enable the control chip 12 to control the storage chips 13 to store data. Therefore, the storage card 100 can communicate with the motherboard 200.

The storage card 100 can be inserted into the expansion slot 21 of the motherboard 200 through the first and second extending boards 20 and 30, to fix the storage card 100 on the motherboard 200, and the storage card 100 communicates with the motherboard 200 through the USB interface 11. The storage card 100 can add storage capacity of the motherboard 200 and can be hot plugged from the expansion slot 21 when the motherboard 200 is powered up.

Even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. A storage card comprising:
a circuit board;
a USB interface arranged on the circuit board, to be connected to a storage device interface of a motherboard;
a control chip arranged on the circuit board and connected to the USB interface;
a plurality of storage chips arranged on the circuit board, and connected to the control chip and the USB interface; and
a first extending board extending from a bottom edge of the circuit board, to be inserted into an expansion slot of the motherboard.

2. The storage card of claim 1, wherein a second extending board is extended from the bottom edge of the circuit board, to be inserted into the expansion slot of the motherboard.

3. The storage card of claim 2, wherein the circuit board is rectangular, the bottom edge of the circuit board is a long edge of the circuit board, the first and second extending boards are extended from the bottom edge of the circuit board, and located adjacent to two opposite short edges of the circuit board, respectively.
